(19) United States
(12) Patent Application Publication
(10) Pub. No.: US 2011/0165729 A1
(43) Pub. Date: Jul. 7, 2011

(54) METHOD OF PACKAGING SEMICONDUCTOR DEVICE

(75) Inventors: Peng LIU, Tianjin (CN); Xu Gao, Tianjin (CN); Qingchun He, Tianjin (CN); Zhaobin Qi, Tianjin (CN); Dehong Ye, Tianjin (CN)

(73) Assignee: FREESCALE SEMICONDUCTOR, INC, Austin, TX (US)

(21) Appl. No.: 12/830,424

(22) Filed: Jul. 5, 2010

(30) Foreign Application Priority Data
Jan. 5, 2010 (CN) 201010002106.7

(51) Int. Cl. H01L 21/78; H01L 21/98; H01L 21/60

(52) U.S. Cl. 438/107; 438/123; 438/111; 257/E21.599; 257/E21.705; 257/E21.509

(57) ABSTRACT

Quad Flat No-Lead packaged devices are manufactured using two singulation operations with two different saw blades of varying widths with the first singulation operation using a wider saw blade than the second singulation operation. Between singulation operations, the exposed portions of the leads are plated with a solderable metal. By performing the second singulation operation within the first cut made by the first singulation, at least half of the exposed metal of the leads remains plated. Thus, better solder joints may be formed, which allows for simpler visual inspection.

### BACKGROUND OF THE INVENTION

The present invention relates generally to semiconductor device packaging, and more particularly to a method of plating and separating a lead frame of a packaged device from the lead frames of other packaged devices.

There is a continuous drive to make electrical appliances such as computers, televisions, stereos, cell phones, etc. smaller, which drives the need for more highly integrated semiconductor devices in smaller packages. That is, there is a need for semiconductor devices with smaller foot prints. One type of semiconductor package is known as a Quad Flat Pack (QFP). FIG. 1 is a side cross-sectional view of a QFP device 10. The QFP device 10 includes a semiconductor die 12, which is an integrated circuit formed in Silicon, attached to a flag 14 of a lead frame with epoxy 16. The die 12 is electrically connected to leads 18 with wires 20, typically via a wire bonding process. The die 12, flag 14, wires 20 and part of the leads 18 are encapsulated with a plastic mold compound 22 for protecting the die 12 and wires 20. The leads 18 are bent and extend out of the sides of the mold compound 22. The leads 18 allow the QFP device 10 to be attached to a printed circuit board (not shown) for connection to other devices. The size or foot print of the device is show with line A-A.

FIG. 2 shows a different but similar type of package in which the leads do not extend beyond the mold compound. This type of package is known as a Quad Flat No-lead (QFN) package. Referring now to FIG. 2, an enlarged, cross-sectional side view of a QFN device 30 is shown. The QFN device 30 includes a semiconductor die 32 having an integrated circuit (IC) formed therein and a plurality of wire bonding pads that allow for connectivity to the IC. The die 32 is attached to a flag 34 with an adhesive 36 such as epoxy. The IC bonding pads are electrically connected to leads 38 with wires 40, and then the die 32, wires 40 and top surfaces of the flag 34 and leads 38 are covered with a mold compound or encapsulant 42. By eliminating external leads, the package footprint can be decreased by almost 50%. Line B-B indicates the footprint of the device 30, which can be seen is much less than that of the device 10 (FIG. 1).

The distal ends and bottom surfaces of the leads 38 are exposed to allow external connection of the device 30 to a printed circuit board (PCB). However, unlike with the QFP device 10, the solder joints of the QFN device 30 are formed underneath the package. Thus, conventional visual inspection techniques to check the quality of the solder joint are difficult and time consuming to perform. For example, it may be necessary to tilt the PCB to inspect the solder joints. Optical and X-ray inspections may be performed but these procedures are expensive and require special equipment. Micro-sectioning is another method of inspecting solder joints but this method is not really useful for production inspection. Thus, it would be desirable if it were easier to inspect such solder joints.

FIG. 3 is a flow chart of a method for manufacturing the QFN device 30. In a first step 50, a lead frame is plated with Sn or Pb or the like. That is, the lead frame (die pad and leads) typically is formed of a conductive material, such as copper foil, and usually a plurality of lead frames is formed from a sheet of copper foil by cutting, punching, stamping or combinations of these processes and then plural packages are assembled simultaneously. To provide for good bonding between the leads and the PCB, either the whole or selected portions of the lead frame are plated with another material such as Tin, Nickel, Palladium, or Gold. In step 52, die attachment, electrical connection, and encapsulation are performed. In step 54, saw singulation is performed to separate devices formed at the same time. In the singulation operation, a rotating saw blade is used to separate simultaneously formed devices formed on a lead frame array. However, after sawing, the bare metal of the lead frame is exposed. That is, unplated portions of the lead frame are exposed.

FIG. 4 is an enlarged photograph of the solder joints beneath a conventionally made QFN device. The photograph shows that the solder joints or rather the extensions of the solder connected to the copper of the lead frame are not clear because the solder joints are made to the bare copper and not a plated surface. Thus, it would be desirable to be able to form more clear solder joints for visual inspection purposes.

### BRIEF DESCRIPTION OF THE DRAWINGS

The invention, together with objects and advantages thereof, may best be understood by reference to the following description of the presently preferred embodiments together with the accompanying drawings. In the drawings, like numerals are used for like elements throughout.

FIG. 1 is an enlarged cross-sectional side view of a conventional QFP device;

FIG. 2 is an enlarged cross-sectional side view of a conventional QFN device;

FIG. 3 is a flow chart of a conventional method of manufacturing the QFN device of FIG. 2;

FIG. 4 is an enlarged photograph of solder joints formed between a PCB and the QFN device of FIG. 2;

FIG. 5 is a flow chart of a method of manufacturing a QFN device according to an embodiment of the present invention;

FIG. 6 is an enlarged photograph of solder joints formed between a PCB and a QFN device manufactured according to the process shown in FIG. 5;

FIGS. 7A-7F illustrate the steps of a singulation operation in accordance with an embodiment of the present invention; and

FIGS. 8A-8D are enlarged photographs of a bottom surface of a QFN device at various stages of a singulation operation in accordance with an embodiment of the present invention.

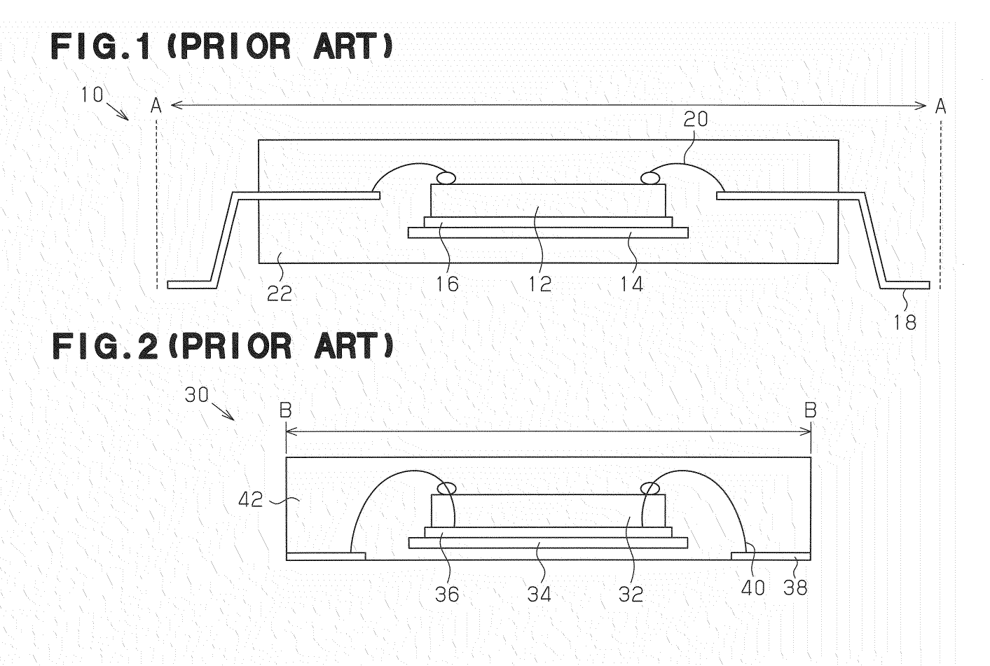

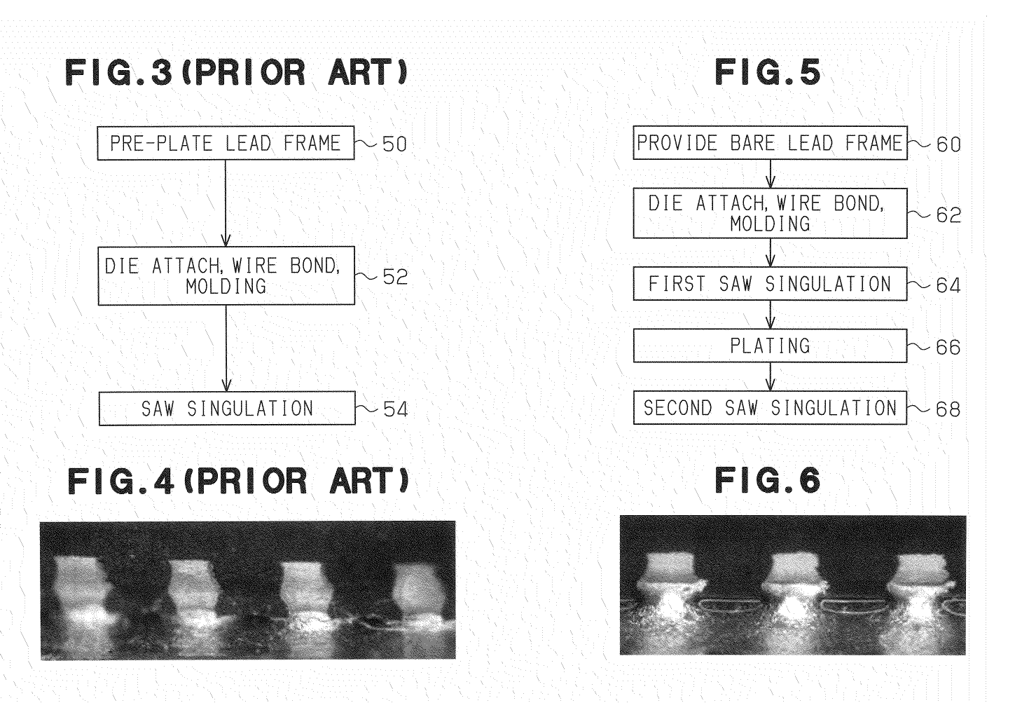

Those of skill in the art will appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE INVENTION

The present invention is illustrated by way of example and is not limited by the accompanying figures, in which like references indicate similar elements.

In one embodiment, the present invention provides a method of packaging a plurality of semiconductor devices. The method includes providing a lead frame strip including a plurality of individual lead frames. Each lead frame has a plurality of leads, and each lead has a first end and a second end. The leads extend outwardly from a generally rectangular central space. The first ends of the leads are proximate to the central space and the second ends are distal from the central space. One or more die pads are disposed in the central space, and saw streets are located between adjacent lead frames of the plurality of lead frames.

The method includes attaching semiconductor dies on respective first ones of the one or more die pads of the individual lead frames. Each die has an integrated circuit formed therein. Next, the leads of the individual lead frames are connected to the respective integrated circuits of the dies. The semiconductor dies, the electrical connections and the leads of the individual lead frames are then encapsulated with a mold compound, but at least a bottom surface of the second ends of the leads is exposed. A first singulation is performed with a first saw blade having a first blade width, along the saw streets. The first singulation cuts the leads of the lead frames to a first depth. Exposed portions of the lead frames are then plated with a solderable metal. A second singulation is performed with a second saw blade having a second blade width, along the saw streets and within spaces made by the first singulation. The second singulation separates the lead frames from each other, thereby forming individual semiconductor packages.

Referring now to FIG. 5, a flow chart of a method for manufacturing semiconductor devices is shown. The method is targeted for QFN type packaged devices, however, as those of skill in the art will appreciate, the method may be practiced when manufacturing other types of packaged devices. At step 60, a lead frame is provided. Typically the lead frame will be part of an array of lead frames or a strip of lead frames formed from a malleable, conductive metal. In the current embodiment, the lead frame is formed from a sheet of copper foil by punching, stamping or cutting, as is known in the art. The copper lead frame may be plated with a solderable metal, such as tin, zinc, gold, silver or palladium. However, a pre-plated lead frame is not required because in accordance with an embodiment of the invention, the lead frame is plated after a first saw singulation step. Each lead frame includes a plurality of leads surrounding a generally central area. The central area may include a die pad or flag. The leads have a first end that is proximal to the die pad and a second or distal end that is further away from the die pad. The leads may surround the central area on one, two, three or all four sides (in the case where the central area is rectangular).

Next, at step 62, semiconductor dies having integrated circuits (IC) formed therein and a plurality of bonding pads formed on surfaces thereof are attached to the die pads of the respective lead frames. Such semiconductor die and integrated circuits are well known by those of skill in the art and further description of the die or IC is not necessary for a complete understanding of the invention. Furthermore, more than one semiconductor die or electrical component (e.g., capacitors) may also be attached to the lead frame.

The dies may be attached to the die pads using known die attach adhesives, e.g., epoxy. The leads of the lead frames are then electrically connected to the die bonding pads using wires via known wire bonding techniques and wire bonding machines. Typically, the die bonding pads are electrically connected to the proximal ends of the leads. After the electrical connections are made, a molding or encapsulation step is performed in which the dies, the wires interconnecting the die bonding pads and the leads, and the top surfaces of the leads are covered with a mold compound. Encapsulation and mold compounds are well known in the art and further description is not required for a complete understanding of the present invention.

At step 64, after the mold compound has cured, a first saw singulation is performed. Singulation is the process of separating the lead frames in the array from each other, thereby providing individual packaged devices. Lead frame arrays and strips usually have saw streets between adjacent lead frames where the lead frame arrays are cut. In accordance with an embodiment of the present invention, the first saw singulation is performed using a first saw blade having a first size or width. The first blade cuts the lead frames along the saw streets to a predetermined depth, which in a presently preferred embodiment of the invention is to about one-half of the thickness of the leads. A saw blade having a first predetermined blade width also is used. In one embodiment of the invention, the first predetermined blade width is 0.58 mm. The first singulation causes portions of the leads to be exposed, i.e., where the saw cuts the leads.

In order to provide for a more well defined solder connection when the finished device will be attached to a printed circuit board (PCB) or some other substrate or device, at step 66 these newly exposed portions of the lead frames are plated with a solderable metal such as tin or palladium. Such solderable metals used for plating lead frames are well known and readily commercially available. Plating processes are also well known.

When the plating process is completed, a second saw singulation step is performed at step 68. In the second saw singulation step, a second saw blade having a second predetermined blade width is used to cut along the saw streets and within spaces made by the first singulation step. The second singulation cuts through the leads and encapsulation material and separates the lead frames from each other, thereby forming individual semiconductor packages. In one embodiment of the invention, the second predetermined blade width is less than the first predetermined blade width, and in one embodiment, the second blade width is about 0.50 mm. Because two singulation steps are performed, a plating process is performed in between cuts, and the first saw blade is wider than the second saw blade, about half of a side wall of the leads at the saw streets remains plated with the solderable metal after the second singulation. Thus, as can be seen in FIG. 6, which is an enlarged photograph of solder joints between a packaged device manufactured according to an embodiment of the invention, as described above, solder joints with more readily visible extensions may be formed and thus visual inspection of finished goods is more readily accomplished.

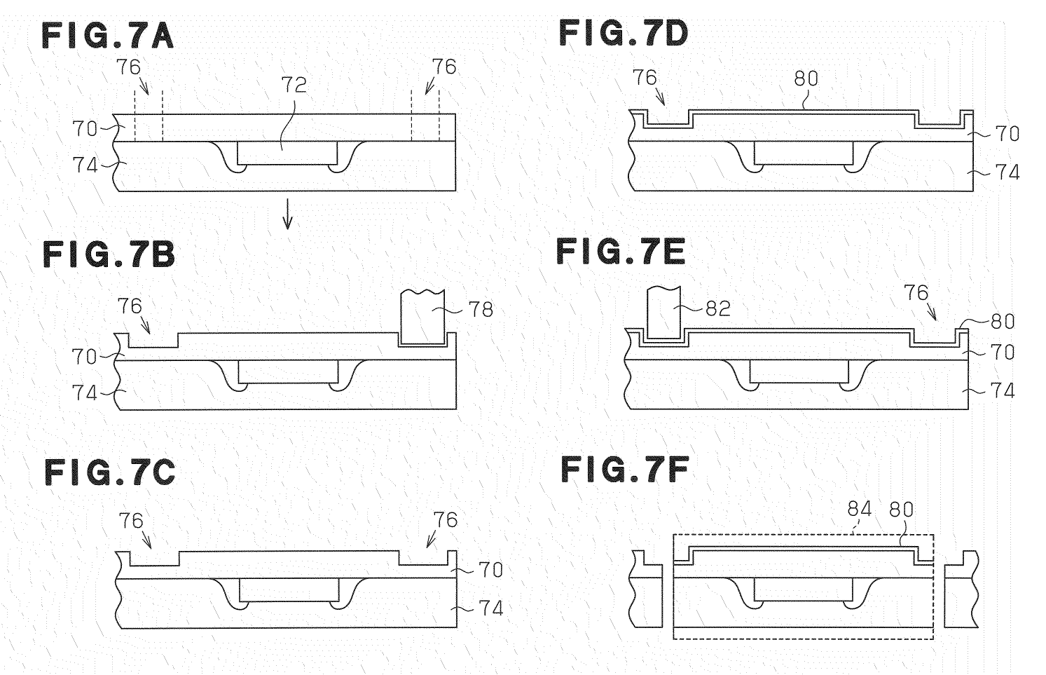

FIGS. 7A to 7F illustrate simplified cross-sectional views of a portion of a lead frame array that illustrate various steps of a method in accordance with an embodiment of the present invention. Beginning with FIG. 7A, a lead frame 70 to which a die 72 has been attached, electrically connected, and encapsulated with an encapsulation material 74 is shown. The lead frame 70 may comprise a frame formed of a conductive metal such as copper or a pre-plated metal frame such as copper plated with tin. In this embodiment, the lead frame 70 includes a flag or die pad to which the die 72 is affixed. Saw streets 76 on opposite sides of the die 72 are also shown.

FIG. 7B illustrates a first singulation operation being performed, where the saw street 76 on the left side of the figure has been cut and the saw street 76 on the right side of the figure undergoing cutting with a first saw blade 78. The saw blade 76 has a first predetermined width and is used to cut into the lead frame 70 to a depth that is about half of the thickness of the lead frame. In one embodiment of the invention, a Z1 size saw blade having a blade width of about 0.58 mm is used. FIG. 7C shows both saw streets 76 after the first singulation operation.

FIG. 7D illustrates the lead frame 70 after undergoing a plating operation in which the lead frame has been plated with a solderable metal finish 80 such as tin. The metal finish 80 also may protect the exposed portions of the lead frame from corrosion and oxidation. In one embodiment, the lead frame 70 is finished with a porous solderable metal finish such that whiskering is reduced or prevented. The metal finish 80 has a thickness sufficient to coat the outer or exposed surface of the lead frame 70. In one embodiment, the metal finish 80 has a thickness of at least approximately 5 microns, or alternatively, at least approximately 9 microns. Alternatively, the metal finish 80 may have a thickness in a range of approximately 5 to 25 microns, or more preferably, 5 to 15 microns. In one embodiment, the metal finish 80 is a porous tin finish. Alternatively, the metal finish 80 may be a tin alloy such as, for example, tin-silver, tin-bismuth, tin-copper, and tin-zinc. Alternatively, other metals or combination of metals may be used for the metal finish 80, for example tin, aluminum, silver, cadmium, zinc, combinations thereof, or alloys of these metals. In one embodiment, the metal finish 80 is formed by plating. For example, the lead frame 70 may be dipped into a plating bath and brought through the plating bath to plate the metal leads and die pad. Note that in alternate embodiments, the metal finish 80 may be formed using other plating methods, such as, for example, electroless plating or fountain plating, where, for example, parameters of these methods may be varied to control the porosity of the metal finish 80.

FIG. 7E illustrates a second singulation operation being performed using a second saw blade 82. The second saw blade 82 has a second predetermined width and is used to cut through the remaining portions of the lead frame 70 at the saw streets 76. The second predetermined width should be less than the first predetermined width (of the first saw blade 78) such that the second blade 82 does not scrape the metal finish 80 on the inner sides of the saw streets 76. In one embodiment of the invention, a Z2 size saw blade having a blade width of about 0.50 mm is used.

FIG. 7F shows a packaged device 84 that has been cut from the lead frame array. As is illustrated, the metal finish 80 remains intact on at least a portion of the inner side of the saw streets. As is understood by those of skill in the art, additional trimming may be performed but care must be taken so that the metal finish at the sides of the package 84 is not removed.

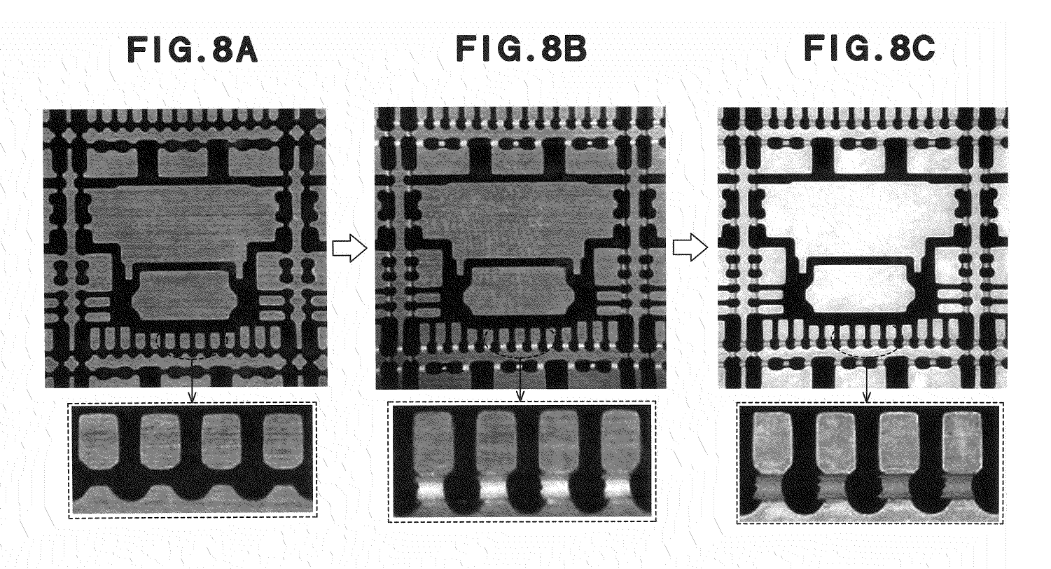

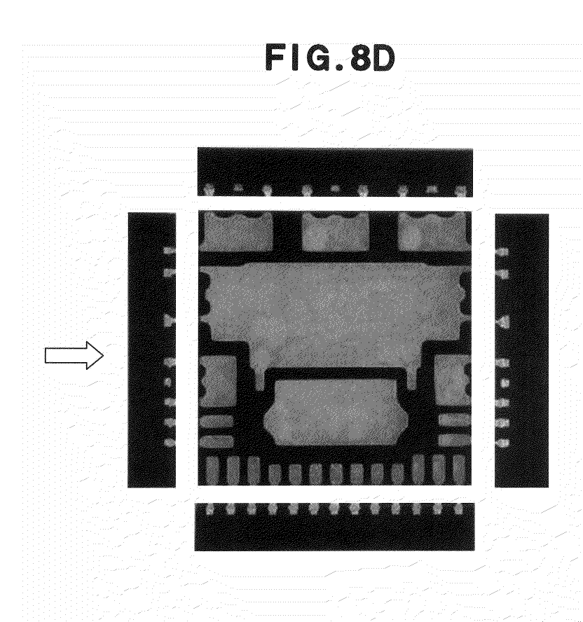

Referring now to FIGS. 8A to 8D, enlarged photographs of a PQFN (Power Quad Flat No lead) packaged device undergoing a singulation operation in accordance with an embodiment of the present invention are shown. FIG. 8A shows a bottom surface of a portion of a lead frame array after a die(s) has been attached to a flag area and electrically connected with leads (ref. FIG. 7A). The extra-enlarged portion of the drawing shows four leads separated from a connection bar with mold compound. FIG. 8B shows the same four after a first singulation operation was performed using first saw blade, as discussed above with reference to FIGS. 7B and 7C. In the first singulation operation, a half-cut was performed. FIG. 8C shows the bottom surface of the device after being plated with a finishing metal, as discussed above with reference to FIG. 7D. Finally, FIG. 8D shows the lead frame array after undergoing a second singulation operation with a second saw blade, as discussed above with reference to FIGS. 7E and 7F.

While embodiments of the invention have been described and illustrated, it will be understood by those skilled in the technology concerned that many variations or modifications in details of design or construction may be made that are still within the scope of the present invention. Also, because the tools for implementing the present invention are, for the most part, well known, as are the circuits, package structure, and compositions used to manufacture devices according to the present invention, details are not be explained in any greater extent than that considered necessary to describe the invention, for the understanding and appreciation of the underlying concepts of the present invention and in order not to obfuscate or distract from the teachings of the present invention.

In the foregoing specification, the invention has been described with reference to specific embodiments. However, one of ordinary skill in the art will appreciate that various modifications and changes can be made without departing from the scope of the present invention as set forth in the claims below. Accordingly, the specification and figures are to be regarded in an illustrative rather than restrictive sense, and all such modifications are intended to be included within the scope of the present invention. Further, relative terms such as “front”, “back”, “top”, “bottom”, “over”, “under” and the like in the description and claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. The terms “a” or “an”, as used herein, are defined as one or more than one. The term “plurality”, as used herein, is defined as two or more than two. The term another, as used herein, is defined as at least a second or more.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims.

1. A method of packaging a plurality of semiconductor devices, the method comprising:
providing a lead frame strip including a plurality of individual lead frames, each lead frame having a plurality of leads, each lead having a first end and a second end, wherein the leads extend outwardly from a generally rectangular central space, the first ends being proximate to the central space and the second ends being distal from the central space, and wherein there are one or more die pads disposed in the central space, and wherein saw streets are located between adjacent lead frames of the plurality of lead frames;
attaching semiconductor dies, each die having an integrated circuit therein, on respective first ones of the one or more die pads of the individual lead frames;
electrically connecting the leads of the individual lead frames to the respective integrated circuits of the dies;
encapsulating the semiconductor dies, the electrical connections and the leads of the individual lead frames with a mold compound, wherein at least a bottom surface of the second ends of the leads is exposed;
performing a first singulation with a first saw blade having a first blade width, along the saw streets, wherein the first singulation cuts the leads of the lead frames to a first depth;
plating exposed portions of the lead frames with a solderable metal; and
performing a second singulation with a second saw blade having a second blade width, along the saw streets and within spaces made by the first singulation, wherein the second singulation separates the lead frames from each other, thereby forming individual semiconductor packages.

2. The method of packaging a plurality of semiconductor devices of claim 1, wherein the lead frame strip comprises copper.

3. The method of packaging a plurality of semiconductor devices of claim 2, wherein the solderable metal comprises one of tin, zinc, palladium and gold.

4. The method of packaging a plurality of semiconductor devices of claim 1, wherein the lead frame strip at the saw streets has a thickness and the first depth is about half of said thickness.

5. The method of packaging a plurality of semiconductor devices of claim 1, wherein the first blade width is greater than the second blade width.

6. The method of packaging a plurality of semiconductor devices of claim 5, wherein the first blade width is about 0.58 mm.

7. The method of packaging a plurality of semiconductor devices of claim 6, wherein the second blade width is about 0.50 mm.

8. The method of packaging a plurality of semiconductor devices of claim 7, wherein by performing first and second singulations, about half of a side wall of the leads at the saw streets remains plated with the solderable metal after the second singulation.

9. A method of packaging a plurality of semiconductor devices, the method comprising:
providing a lead frame strip including a plurality of individual lead frames, each lead frame having a plurality of leads, each lead having a first end and a second end, wherein the leads extend outwardly from a generally rectangular central space, the first ends being proximate to the central space and the second ends being distal from the central space, and wherein there are one or more die pads disposed in the central space, and wherein saw streets are located between adjacent lead frames of the plurality of lead frames;
attaching semiconductor dies, each die having an integrated circuit therein, on respective first ones of the one or more die pads of the individual lead frames;
electrically connecting the leads of the individual lead frames to the respective integrated circuits of the dies;
encapsulating the semiconductor dies, the electrical connections and the leads of the individual lead frames with a mold compound, wherein at least a bottom surface of the second ends of the leads is exposed;
performing a first singulation with a first saw blade having a first blade width, along the saw streets, wherein the first singulation cuts the leads of the lead frames to a first depth;
plating exposed portions of the lead frames with a solderable metal; and
performing a second singulation with a second saw blade having a second blade width, along the saw streets and within spaces made by the first singulation, wherein the first blade width is greater than the second blade width, and wherein the second singulation separates the lead frames from each other, thereby forming individual semiconductor packages.

10. The method of packaging a plurality of semiconductor devices of claim 9, wherein the lead frame strip comprises copper.

11. The method of packaging a plurality of semiconductor devices of claim 10, wherein the solderable metal comprises one of tin, zinc, palladium and gold.

12. The method of packaging a plurality of semiconductor devices of claim 9, wherein the lead frame strip at the saw streets has a thickness and the first depth is about half of said thickness.

13. The method of packaging a plurality of semiconductor devices of claim 9, wherein the first blade width is about 0.58 mm.

14. The method of packaging a plurality of semiconductor devices of claim 13, wherein the second blade width is about 0.50 mm.

15. The method of packaging a plurality of semiconductor devices of claim 9, wherein by performing first and second singulations, about half of a side wall of the leads at the saw streets remains plated with the solderable metal after the second singulation.

16. A method of packaging a plurality of semiconductor devices, the method comprising:
providing a lead frame strip including a plurality of individual lead frames, each lead frame having a plurality of leads, each lead having a first end and a second end, wherein the leads extend outwardly from a generally rectangular central space, the first ends being proximate to the central space and the second ends being distal from the central space, and wherein there are one or more die pads disposed in the central space, and wherein saw streets are located between adjacent lead frames of the plurality of lead frames;
attaching semiconductor dies, each die having an integrated circuit therein, on respective first ones of the one or more die pads of the individual lead frames;
electrically connecting the leads of the individual lead frames to the respective integrated circuits of the dies;
encapsulating the semiconductor dies, the electrical connections and the leads of the individual lead frames with a mold compound, wherein at least a bottom surface of the second ends of the leads is exposed;
performing a first singulation with a first saw blade having a first blade width, along the saw streets, wherein the first singulation cuts the leads of the lead frames to a first depth, wherein the lead frame strip at the saw streets has a thickness and the first depth is about half of said thickness;
plating exposed portions of the lead frames with a solderable metal; and
performing a second singulation with a second saw blade having a second blade width that is less than the first saw blade width, along the saw streets and within spaces made by the first singulation, and wherein the second singulation separates the lead frames from each other, thereby forming individual semiconductor packages, and wherein by performing first and second singulations, about half of a side wall of the leads at the saw streets remains plated with the solderable metal after the second singulation.
